(19) United States
(12) Patent Application Publication
(10) Pub. No.: US 2013/0207109 A1
(43) Pub. Date: Aug. 15, 2013

(54) SEMICONDUCTOR DEVICE AND METHOD FOR MANUFACTURING A SEMICONDUCTOR DEVICE

(71) Applicant: Jerry Wong, San Jose, CA (US)

(72) Inventor: Jerry Wong, San Jose, CA (US)

(73) Assignee: Ji Fu Machinery & Equipment Inc., San Jose, CA (US)

(21) Appl. No.: 13/372,985

(22) Filed: Feb. 14, 2012

(51) Int. Cl. H01L 29/04; H01L 31/18

(52) U.S. Cl. 257/49; 438/97; 257/E29.003; 257/E31.043

(57) ABSTRACT

A method for manufacturing a semiconductor device includes providing a substrate upon which the semiconductor device is to be disposed, heating the substrate to a first temperature that exceeds at least one of a softening point or glass transition temperature of the substrate, and depositing a polysilicon layer onto the substrate. A semiconductor device includes a substrate having at least one of a softening point, Tₛ, that is less than 600 degrees Celsius and a polysilicon layer disposed on an upper surface of the substrate such that the polysilicon layer abuts the substrate.

### BACKGROUND

The subject matter described herein relates to semiconductor devices, such as diodes used for solar cell applications, other photovoltaic devices, photosensors, displays such as Liquid Crystal Displays (LCD), and the like. Some known semiconductor devices include silicon layers formed from silicon. The silicon layers may include intrinsic silicon layer and doped volumes or regions that provide donors and acceptors for the devices or sensors. Alternatively, the silicon layers may provide active layers in the photovoltaic device that absorbs incident light and converts the incident light into an electric current.

In general, the efficiency of the semiconductor device may be dependent upon the crystallinity and/or a defect density of the semiconductor (e.g., silicon) layer in the semiconductor device. For example, single crystal silicon solar cell may have relatively higher efficiencies in converting incident light into electric current than a polysilicon solar cell. Similarly, polysilicon solar cells may have higher efficiencies than that of amorphous silicon cells.

The defect density and crystallinity of the semiconductor (e.g., silicon) layers may be inversely related to the temperature at which the silicon layers are deposited. For example, single crystalline silicon usually forms at temperatures above 1000 degrees Celsius. Polysilicon may form at temperatures of over 500 degrees Celsius. Amorphous silicon, on the other hand, can be deposited at temperatures in the range of 150 to 500 degrees Celsius. Micro-crystalline silicon can be deposited using a similar temperature range as amorphous silicon. Silicon layers that are deposited at lower temperatures with lower crystallinity and higher defect densities may be deposited on relatively inexpensive substrates, such as glass. Such inexpensive substrate may have some undesired properties for certain devices after exposure to high temperature environment.

Examples of such undesirable properties can include relatively large amounts of impurities, such as sodium, being present in the substrates of the devices. These impurities can diffuse into the semiconductor (e.g., silicon) layers disposed above the substrates when the substrate is exposed to a higher temperature environment.

Other undesirable properties of less expensive substrates can include the changing flatness of the substrates during heating of the substrates. For example, some glass substrates may become less planar and have a more undulating surface upon which the semiconductor or other layers are deposited. The changing flatness of the substrates can affect subsequent processing operations. For example, when glass is used for the substrate, during the exposure of the substrate to relatively higher temperatures during deposition of layers on or above the substrate, the glass may become soft and unable to return to an original flat form for subsequent processes, such as a photolithography process that follows deposition of semiconductor material on the substrate. A non-flat surface of the substrate during the photolithography process can negatively impact the subsequent removal or etching of the semiconductor layer due to varying thicknesses and/or angles of an etching mask deposited during the photolithography process (e.g., a photoresist mask).

Conversely, polycrystalline or single crystal silicon layers or wafers may be used in the semiconductor devices. Polycrystalline silicon layers, or polysilicon layers, may be deposited at temperatures of at least 500 to 600 degrees Celsius. Single crystal silicon layers may be deposited at temperatures of at least 1000 degrees Celsius. For the traditional semiconductor or/and LCD manufacturing processes, in order to prevent impurities from diffusing from the substrate into the polysilicon or single crystal silicon layers, or in order to maintain certain physical properties of the substrate and/or semiconductor layers (such as flatness of the substrate and/or semiconductor layers for the subsequent photolithography processes) that the subsequent process may require, relatively expensive substrates may be used. As a result, there may be very few choices of substrates that can be used to deposit polysilicon for semiconductor or/and LCD manufacturing process.

As set forth above, a tradeoff exists between the quality of the semiconductor (e.g., silicon) layers in semiconductor devices and the cost of the substrates used in the semiconductor devices. A need exists to increase the quality of silicon layers in semiconductor devices while avoiding significant increases in the cost of manufacturing the semiconductor devices.

### BRIEF DESCRIPTION

In one embodiment, a method for manufacturing a semiconductor device is provided. The method includes providing a substrate upon which the semiconductor device is to be disposed, heating the substrate to a first temperature that exceeds at least one of a softening point or glass transition temperature of the substrate, and depositing a polysilicon layer onto the substrate.

In another embodiment, a semiconductor device is provided. The semiconductor device includes a substrate having at least one of a softening point, Tₛ, that is less than 600 degrees Celsius and a polysilicon layer disposed on an upper surface of the substrate such that the polysilicon layer abuts the substrate.

### BRIEF DESCRIPTION OF THE DRAWINGS

FIG. 1 is a perspective view of a substrate for a semiconductor device in accordance with one embodiment.

FIG. 2 is a diagram of a heating chamber in accordance with one embodiment.

FIG. 3 is a schematic view of a plasma enhanced chemical vapor deposition (PECVD) chamber in accordance with one embodiment.

FIG. 4 is a schematic view of the substrate shown in FIG. 1 in the PECVD chamber shown in FIG. 3 in accordance with another embodiment.

FIG. 5 is a cross-sectional view of a semiconductor device that includes the substrate shown in FIG. 1 and the polysilicon layer shown in FIG. 3 in accordance with one embodiment.

FIG. 6 is a cross-sectional view of a semiconductor device that includes the substrate shown in FIG. 1 and the polysilicon layer shown in FIG. 3 in accordance with another embodiment.

FIG. 7 is a flowchart for a method of manufacturing a semiconductor device that includes the polysilicon layer shown in FIG. 3 in accordance with one embodiment.

### DETAILED DESCRIPTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

In accordance with one or more embodiments described herein, a solar cell having a polysilicon layer that is directly deposited onto a substrate is provided. The substrate may be formed from a low temperature material, or a material having a relatively low softening point. In one aspect, the substrate may not be flat to meet the normal semiconductor and or flat panel device manufacturing standard before or after the deposition process. In another aspect, prior to depositing the polysilicon layer onto the substrate, the substrate may have a relatively large amount of impurities. The substrate is heated prior to depositing the polysilicon layer to cause the impurities to diffuse out of the substrate. After heating the substrate, the polysilicon layer may be directly deposited onto an upper surface of the substrate without an intervening layer disposed between the polysilicon layer and the substrate. Alternatively, a post-heating cleaning process may be applied to clean off the impurities from the substrate that have been driven out from the substrate by the heating process. In another embodiment, one or more sealing layers may be deposited on the substrate and between the substrate and the polysilicon layer to prevent more of the impurities in the substrate from diffusing out of the substrate and into the polysilicon layer. The polysilicon layer may be manufactured to be part of the photovoltaic cell or module, a diode type of photosensor and the like that may not require post lithography processes.

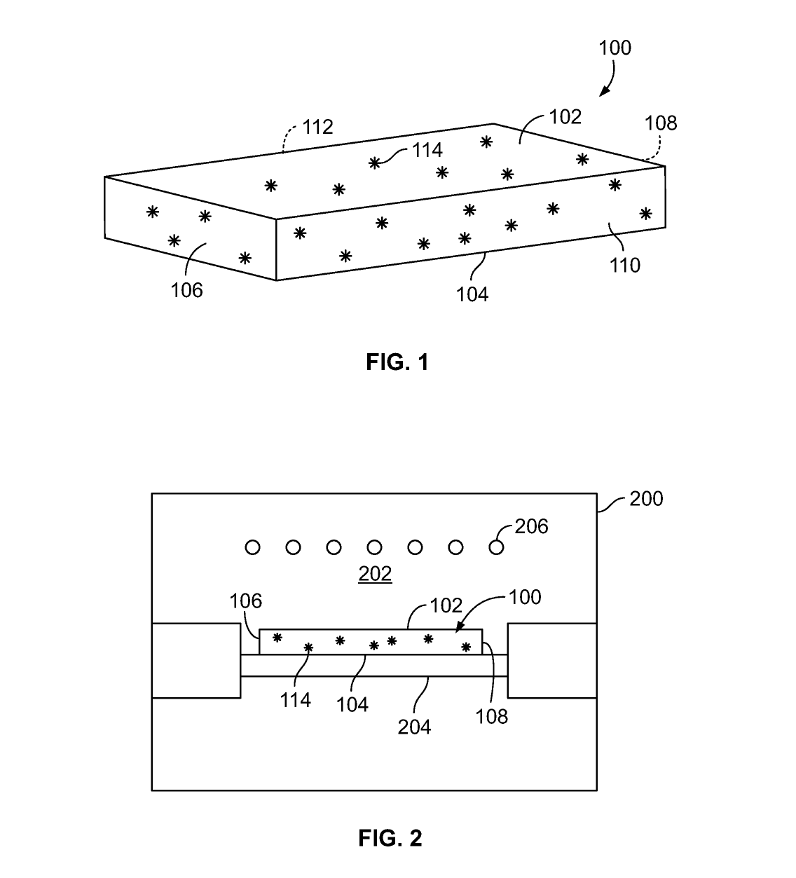

FIG. 1 is a perspective view of a substrate 100 for a semiconductor device in accordance with one embodiment. The substrate 100 may be a supporting surface for the semiconductor device. For example, the substrate 100 may support a semiconductor device that is deposited or otherwise formed on an upper surface 102 of the substrate 100, such as a photovoltaic cell or module, a diode of a photosensor. The substrate 100 has a lower surface 104 that is opposite of the upper surface 102, and opposite edges 106, 108 and opposite edges 110, 112 that interconnect the surfaces 102, 104.

The substrate 100 may have a flat or predominantly flat surface at room temperature (e.g., 21 degrees Celsius). For example, the substrate 100 may not have a concave or convex surface at room temperature. Alternatively, the substrate 100 may have a non-even, wavy, or bowed shape, such that the difference between low portions of the upper surface of the substrate 100 (e.g., the lowest points in the valleys of the upper surface) and the upper portions of the upper surface of the substrate 100 (e.g., the highest points in the peaks of the upper surface) may exceed limits of a photolithography process that is used to etch layers deposited above the substrate 100. In another example, the substrate 100 may have a flat or predominantly flat surface at room temperature and prior to heating the substrate 100 above a temperature, such as a softening point or glass transition temperature of the substrate 100, but after heating the substrate 100, the substrate 100 has a non even or wavy shape, even after returning to room temperature. The shape of a substrate 100 having a non-flat shape, such as a concave or convex shape, may be referred to herein as a non-planar shape. By “concave” or “convex,” it is meant that the global or monolithic shape of the substrate 100, and not just a relatively small portion, of the substrate 100 is bent or bowed.

The substrate 100 is a material having a relatively low softening point in one embodiment. The softening point represents a temperature at which the substrate 100 softens, or changes one or more dimensions of the substrate 100 without external forces being applied to the substrate 100. The softening point of the substrate 100 may be determined according to ASTM Standard C338-93 (reapproved 2008), entitled “Standard Test for Softening Point of Glass.” For example, the softening point of the substrate 100 may be determined by creating a round fiber sample of the material from which the substrate 100 is formed having a diameter of approximately 0.65 millimeters and a length of approximately 235 millimeters. At least a portion of the sample is heated at a temperature that increases at a rate of 4 to 6 degrees Celsius per minute. For example, a portion of the sample that extends from one end of the sample to 100 millimeters along the length of the sample may be heated. The softening point may be identified as the temperature at which the sample elongates under its own weight at a rate of at least 1 millimeter per minute, as described in the ASTM Standard 338-93.

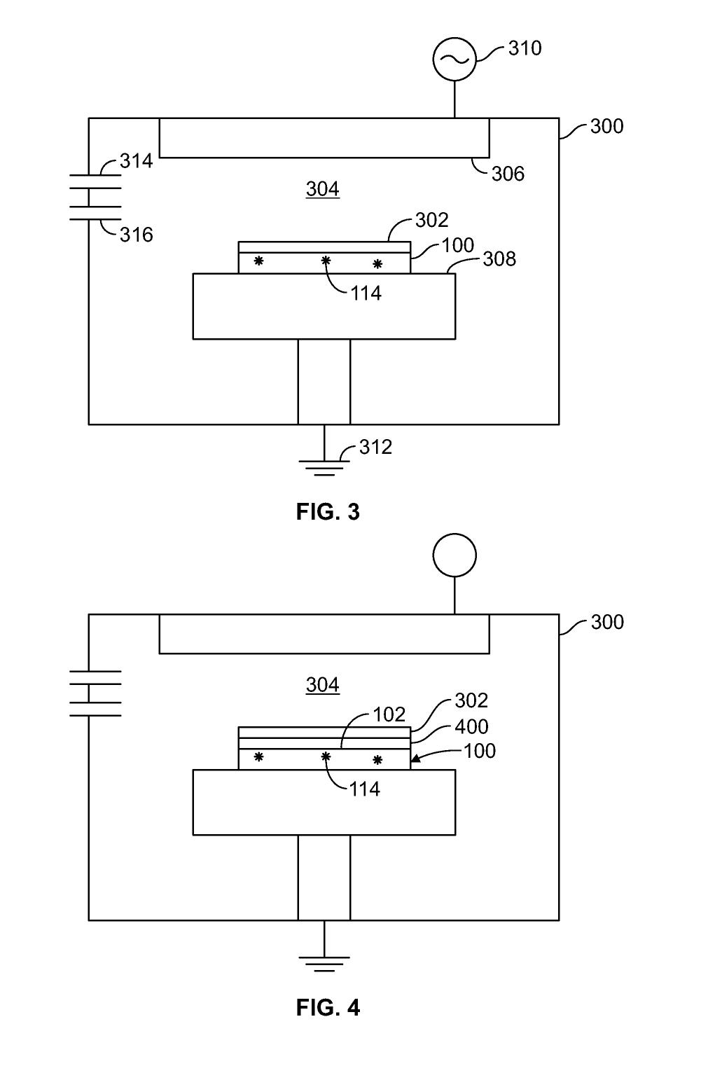

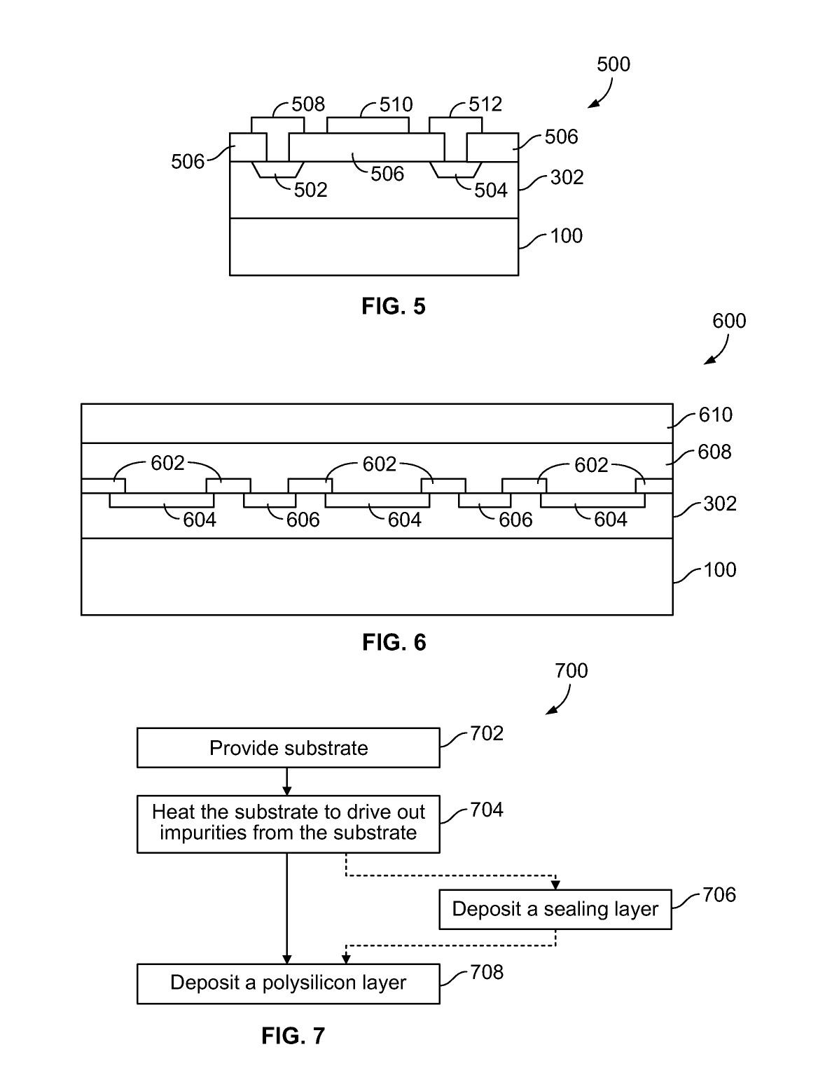

In one embodiment, the substrate 100 has a softening point that is below 600 degrees Celsius. Alternatively, the substrate 100 may have a higher softening point, such as below 730 degrees Celsius, below 750 degrees Celsius, or below 850 degrees Celsius. The substrate 100 may have a relatively low softening point due to the presence of the impurities 114 in the substrate 100. The substrate 100 may be formed from relatively inexpensive materials that include significant amounts of impurities 114 that could negatively impact the performance of the semiconductor device disposed on the substrate 100 if the impurities 114 diffuse into a crystal silicon (e.g., polysilicon) layer 302 (shown in FIG. 3) that is deposited onto the substrate 100.

The substrate 100 may be formed from a material that softens (e.g., becomes more elastic, more deformable, or as measured by one or more techniques, such as the Vicat softening point) at a relatively low temperature and/or has a relatively low glass transition temperature (T_{g}). The glass transition temperature (T_{g}) is the temperature at which a glass-forming liquid transforms into a glass. The glass transition temperature (T_{g}) may be determined by one or more test methods set forth in ASTM Standards, such as ASTM Standard E2602-09 (“Standard Test Method for the Assignment of the Glass Transition Temperature by Modulated Temperature Differential Scanning calorimetry.” The ASTM Standard E2602-09 describes several test methods for identifying the glass transition temperature (T_{g}) of a material, such as by using differential scanning calorimetry, thermomechanical analysis, or dynamic mechanical analysis. In one embodiment, the substrate 100 has a glass transition temperature (T_{g}) that is less than 600 degrees Celsius.

The substrate 100 may have the presence of a significant amount of the impurities 114 in the substrate 100. For example, the substrate 100 can be formed from a material having a significant amount of a metal, such as sodium (Na), in the substrate 100. The metal can be an impurity 114 that, if permitted to diffuse into the polysilicon layer 302 (shown in FIG. 3), would negatively impact the semiconductor device that includes the polysilicon layer 302.

In another embodiment, the substrate 100 may be formed from a metal. For example, the substrate 100 may include or be formed from a metal, such as nickel, stainless steel, aluminum, or titanium, or a metal alloy that includes nickel, stainless steel, aluminum, or titanium

In another embodiment, the substrate may be formed by any other material that may or may not change flatness during high temperature processing steps, such as a ceramic material.

FIG. 2 is a diagram of a heating chamber 200 in accordance with one embodiment. The heating chamber 200 is shown as one example of a device that may be used to heat the substrate 100. Prior to depositing the polysilicon layer 302 (shown in FIG. 3) onto the substrate 100, the substrate 100 is placed into the heating chamber 200. The heating chamber 200 includes an interior compartment 202 into which the substrate 100 is placed. The interior compartment 202 may include a support 204 formed from quartz or another type of material that does not chemically react or diffuse into the substrate 100. Several lamps 206 are disposed above the substrate 100 and generate heat that increases the temperature inside the interior compartment 202 and of the substrate 100. The lamps 206 may be formed from resistive elements, such as wires, across which a current is applied. The resistance of the lamps 206 causes the lamps 206 to generate heat from passage of the current through the lamps 206.

The substrate 100 is heated by the lamps 206 to drive out impurities 114 from the substrate 100. As the temperature of the substrate 100 increases, the impurities 114 in the substrate 100 may diffuse through the substrate 100. For example, sodium ions located within the substrate 100 may move toward the upper surface 102, the lower surface 104, and/or one or more of the edges 106, 108, 110, 112 (shown in FIG. 1) when the thermal energy of the substrate 100 is increased from the heat generated by the lamps 206. The substrate 100 is heated at a sufficiently high temperature that a significant portion of the impurities 114 diffuse out of the substrate 100 through the surfaces 102, 104 and/or edges 106, 108, 110, 112.

In one embodiment, the substrate 100 is heated to a temperature set point that exceeds the softening point and/or the glass transition temperature (T_{g}) of the substrate 100. The temperature set point may be the temperature of the space or gas inside the interior compartment 202. Alternatively, the temperature set point may be the temperature of the substrate 100. The substrate 100 may be heated to a temperature set point that is greater than the softening point and/or glass transition temperature (T_{g}), but within 10%, 20%, 30%, 40%, 50%, and the like, of the softening point and/or glass transition temperature (T_{g}). As the temperature at which the substrate 100 is heated increases, the impurities 114 may diffuse out of the substrate 100 at faster rates.

The substrate 100 may be heated at the temperature set point for a dwell time. The dwell time represents the time period that the substrate 100 is heated at the temperature set point. The dwell time may be based on the amount of impurities 114 in the substrate 100. The dwell time may be longer for substrates 100 having greater amounts of impurities 114 than for substrates 100 having lesser amounts of impurities 114. By way of example only, the dwell time for a substrate 100 formed from a glass having 13% by weight of sodium oxide (Na₂O) may be longer than the dwell time for a substrate 100 formed from a glass having 10% by weight of sodium oxide (Na₂O). The dwell time may be sufficiently long such that the percentage by weight of an impurity in the substrate 100 is reduced by at least a predetermined threshold percentage, such as 50%, 75%, 90%, 95%, or 99%. For example, the dwell time may be sufficiently long that a substrate 100 originally having 10% by weight sodium oxide (Na₂O) is heated at a temperature set point for a dwell time that causes 99% of the sodium in the substrate 100 to diffuse out of the substrate 100.

The dwell time may be based on the temperature set point. As described above, certain impurities 114 may diffuse out of the substrate 100 at greater temperatures. Therefore, the dwell time may increase for lower temperature set points and decrease for higher temperature set points.

Once the substrate 100 has been heated, at least some of the impurities 114 in the substrate 100 may be driven out the impurities 114 from the substrate 100. The substrate 100 can be taken to the next process sequence, and may be required to be removed from a special heating chamber 200 and the polysilicon layer 302 (shown in FIG. 3) can be deposited onto the substrate 100.

FIG. 3 is a schematic view of a chemical vapor deposition (CVD) chamber 300 in accordance with one embodiment. The CVD chamber 300 may be used to deposit the polysilicon layer 302 onto the substrate 100. The CVD chamber 300 is enclosed to allow a vacuum environment to be established in an interior space 304 of the CVD chamber 300. The CVD chamber may be equipped with electrode plates 306, 308 connected to a radio frequency (RF) source 310 or a remote plasma source.

The substrate 100 is positioned between the upper and lower heater. One or more deposition gases are fed into the interior space 304 through inlets 314, 316. For example, one or more of hydrogen containing gas, a gas that includes silicon, a gas that includes boron, or phosphorous containing gas may be fed into the chamber 300 through the inlets 314, 316. The deposition gas enters into the space between the substrate 100 and the heater 306, 308. The high enough temperature 306, 308 ionizes, or “cracks,” the deposition gas to create ionized gas. The ionized gas deposits material on the substrate 100 to grow films and layers on the substrate 100, such as the polysilicon layer 302.

The interior space 304 of the CVD chamber 300 may be heated to a temperature set point during the deposition of the polysilicon layer 302. For example, the interior space 304 may be heated to assist in the formation of the layer 302 as a crystalline or polycrystalline layer. In general, as the heat of the interior space 304 is increased during deposition of a silicon layer, the more crystalline the silicon layer may become. In one embodiment, the temperature set point of the CVD chamber 300 is at least 450 degrees Celsius during deposition of the polysilicon layer 302. In another embodiment, the temperature set point of the CVD chamber 300 is at least 500 degrees Celsius during deposition of the polysilicon layer 302. Alternatively, the temperature set point for deposition of the polysilicon layer 302 may be at least 550 or at least 600 degrees Celsius. In another embodiment, the temperature set point for the deposition of the polysilicon layer 302 is at least 1000 degrees Celsius.

The temperature set point used to deposit the polysilicon layer 302 may be sufficiently high to provide a polycrystalline structure of the silicon in the layer 302, while sufficiently low to prevent a significant amount of remaining impurities 114 in the substrate 100 from diffusing out of the substrate 100 and into the polysilicon layer 302. For example, the substrate 100 may be heated at a temperature set point that is less than the temperature set point at which the substrate 100 was heated to remove at least some of the impurities 114. In one embodiment, the substrate 100 is heated at a temperature set point in the PECVD chamber 300 that is less than the softening point and/or glass transition temperature (T_{g}) of the substrate 100.

In the illustrated embodiment, the polysilicon layer 302 is formed as a silicon film that is directly deposited onto the upper surface 102 of the substrate 100. For example, the polysilicon layer 302 may be directly deposited onto the upper surface 102 such that the polysilicon layer 302 abuts the upper surface 102 without any intervening or intermediate layers disposed between the polysilicon layer 302 and the substrate 100. The polysilicon layer 302 may include one or more junctions or regions of doped semiconductor material, such as a P-N, N-P, N-I-P or P-I-N junction stack of doped silicon films for a photovoltaic device, doped source and/or drain regions for a transistor device, and the like.

FIG. 4 is a schematic view of the substrate 100 in the PECVD chamber 300 in accordance with another embodiment. Instead of directly depositing the polysilicon layer 302 onto the substrate 100 (and as shown in FIG. 3), a sealing layer or a barrier layer 400 may be deposited on the substrate 100 prior to depositing the polysilicon layer 302. For example, the sealing layer or a barrier layer 400 may be directly deposited onto the upper surface 102 of the substrate 100 using the PECVD chamber 300 and the polysilicon layer 302 may be directly deposited onto the sealing layer 400.

In one embodiment, the sealing layer 400 is a nitride layer that includes one or more nitride films. For example, the sealing layer 400 may include or be formed from silicon nitride (Si₃N₄). Alternatively, the sealing layer 400 may include a stack of oxide layers disposed on opposite sides of a nitride layer, otherwise referred to as an ONO layer for oxide-nitride-oxide layer. A first one of the oxide layers can be directly deposited onto the upper surface 102 of the substrate 100 with the nitride layer above the first oxide layer and a second oxide layer on top of the nitride layer. The polysilicon layer 302 may be deposited onto the second oxide layer. The oxide layers may be formed from or include silicon dioxide (SiO₂) while the nitride layer may include or be formed from silicon nitride (Si₃N₄). However, other oxides and nitrides are within the scope of one or more embodiments described herein.

In one embodiment, the barrier layer that includes one or more of the conducting films. For example, the barrier layer may include, be formed from, or be deposited on Titanium Nitride.

The sealing layer or a barrier layer 400 is deposited onto the substrate 100 to seal or block certain undesired impurities 114 in the substrate 100 into the substrate 100 and/or to provide a buffer film or films that provide transitions between the substrate 100 and one or more layers that are deposited above the substrate and the layer 400. The sealing layer or a barrier layer 400 prevents the impurities 114 from diffusing out of the substrate 100 during subsequent heat treatment steps of the polysilicon layer 302. For example, the sealing layer 400 may be deposited to prevent impurities 114 from diffusing into the polysilicon layer 302 during deposition of the polysilicon layer 302 and/or during the heating of the substrate 100 during the deposition of additional layers on the polysilicon layer 302, the crystallization of the polysilicon layer 302 or other layers deposited above the polysilicon layer 302, ion implantation of the polysilicon layer 302 or other layers deposited above the polysilicon layer 302, and the like. These additional heat treatment steps occur subsequent to the deposition of the polysilicon layer 302 on the sealing layer 400 and may occur at temperatures that are sufficiently high that the impurities 114 would otherwise diffuse out of the substrate 100 and into the polysilicon layer 302. The sealing layer 400 acts as a barrier to the diffusion of the impurities 114 into the polysilicon layer 302.

Various types of devices can be formed using the substrate 100 and polysilicon layer 302. For example, solid state transistor devices, diodes, photovoltaic devices (e.g., solar cells), or the like, may be formed from and include the substrate 100 and the polysilicon layer 302. In one embodiment, the a photovoltaic device that includes one or more solar cells that convert incident light into electric current are formed from layers deposited on the substrate 100, with the polysilicon layer 302 including at least part of the active layers of the photovoltaic device that convert incident light into electric current.

FIG. 7 is a flowchart for a method 700 of manufacturing a semiconductor device that includes the polysilicon layer 302 in accordance with one embodiment. At 702, the substrate 100 (shown in FIG. 1) is provided. As described above, the substrate 100 may be formed from a material having a relatively low softening point and/or glass transition temperature (T_{g}). For example, the softening point and/or glass transition temperature (T_{g}) of the substrate 100 may be lower than one or more processing steps involved in manufacturing the semiconductor device that includes the substrate 100.

At 704, the substrate 100 (shown in FIG. 1) is heated. The substrate 100 is heated to cause impurities 114 (shown in FIG. 1) in the substrate 100 to diffuse out of the substrate 100. The substrate 100 may be heated at a temperature that is greater than the softening point and/or glass transition temperature (T_{g}) of the substrate 100.

In one embodiment, flow of the method 700 proceeds from 704 to 708. At 708, the polysilicon layer 302 (shown in FIG. 3) is deposited onto the substrate 100 (shown in FIG. 1). As described above, the polysilicon layer 302 may be directly deposited onto the upper surface 102 (shown in FIG. 1) of the substrate 100 without any intervening layers between the polysilicon layer 302 and the substrate 100. The deposition of the polysilicon layer 302 may involve heating the substrate 100 to a temperature that is less or cooler than the softening point and/or glass transition temperature (T_{g}) of the substrate 100. The driving out of the impurities 114 (shown in FIG. 1) from the substrate at 704 may prevent the impurities 114 from diffusing into the polysilicon layer 302 during the deposition of the polysilicon layer 302. Alternatively, the polysilicon layer 302 may be deposited at a temperature that is greater than the softening point and/or glass transition temperature (T_{g}) of the substrate 100.

The polysilicon layer 302 (shown in FIG. 3) is deposited in a polycrystalline or microcrystalline state in one embodiment. For example, the polysilicon layer 302 may not be deposited in an amorphous state and then heated to form a polycrystalline or microcrystalline structure. Conversely, the polysilicon layer 302 may be deposited in an amorphous state and then heated to form a polycrystalline or microcrystalline structure.

In another embodiment, flow of the method 700 proceeds from 704 to 706, and then from 706 to 708. At 706, the sealing layer 400 (shown in FIG. 4) is deposited on the substrate 100 (shown in FIG. 1). For example, the sealing layer 400 may be directly deposited onto the upper surface 102 (shown in FIG. 1) of the substrate 100. The sealing layer 400 seals in remaining impurities 114 (shown in FIG. 1) in the substrate 100 so that the impurities 114 cannot diffuse out of the substrate 100 through the upper surface 102 during subsequent heat treatment steps or processes.

Flow of the method 700 may proceed from 706 to 708, where the polysilicon layer 302 (shown in FIG. 3) is deposited onto the sealing layer 400 (shown in FIG. 4). For example, the polysilicon layer 302 may be deposited such that the sealing layer 400 is disposed between and extends from the substrate 100 (shown in FIG. 1) and the polysilicon layer 302.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter set forth herein without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter described herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A method for manufacturing a semiconductor device use for in a photovoltaic device, the method comprising:
providing a substrate upon which the semiconductor device is to be disposed;
heating the substrate to a first temperature that exceeds a softening point of the substrate; and
depositing a polysilicon layer onto the substrate.

2. The method of claim 1, wherein providing the substrate includes providing a convex substrate or a concave substrate.

3. The method of claim 1, wherein the heating comprises maintaining the substrate at the first temperature for a dwell time, the dwell time being of sufficiently long duration to drive out impurities from the substrate.

4. The method of claim 1, wherein the heating comprises heating the substrate to greater than 600 degrees Celsius.

5. The method of claim 1, wherein the substrate is formed from a glass that includes sodium.

6. The method of claim 1, wherein the substrate is formed from a metal.

7. The method of claim 1, wherein the depositing comprises depositing the polysilicon layer at a second temperature that is cooler than the first temperature.

8. The method of claim 1, wherein the depositing comprises directly depositing the polysilicon layer onto an upper surface of the substrate without an intervening layer disposed between the polysilicon layer and the substrate.

9. The method of claim 1, further comprising depositing a sealing layer on the substrate and the depositing the polysilicon layer comprises depositing the polysilicon layer on the sealing layer.

10. The method of claim 9, wherein the sealing layer includes a nitride material.

11. A semiconductor device comprising:
a substrate having a non-planar shape at room temperature and prior to heating the substrate at a temperature above 600 degrees Celsius or having the non-planar shape after being heated to the temperature above 600 degrees Celsius and returning to the room temperature; and
a polysilicon layer disposed on an upper surface of the substrate such that the polysilicon layer abuts the substrate.

12. The semiconductor device of claim 11, wherein the substrate is formed from a glass that includes sodium.

13. The semiconductor device of claim 11, wherein the substrate is formed from a metal.

14. The semiconductor device of claim 11, wherein the polysilicon layer directly abuts the substrate without an intervening layer disposed between the polysilicon layer and the substrate.

15. The semiconductor device of claim 11, further comprising a sealing layer disposed between the substrate and the polysilicon layer.

16. The semiconductor device of claim 15, wherein the sealing layer includes a nitride material.

17. The semiconductor device of claim 11, wherein the semiconductor device is at least one of a transistor or photovoltaic device that includes the polysilicon layer.
